(19) United States
(12) Patent Application Publication
(10) Pub. No.: US 2026/0068619 A1
(43) Pub. Date: Mar. 5, 2026

(54) SUBSTRATE PROCESSING METHOD AND SUBSTRATE PROCESSING APPARATUS

(71) Applicant: Tokyo Electron Limited, Tokyo (JP)

(72) Inventors: Masahito SUGIURA, Nirasaki-shi (JP); Takashi MATSUMOTO, Nirasaki-shi (JP); Yukihiro MUTA, Nirasaki-shi (JP)

(21) Appl. No.: 19/381,251

(22) Filed: Nov. 6, 2025

Related U.S. Application Data
(63) Continuation of application No. PCT/JP2024/016621, filed on Apr. 30, 2024.

(30) Foreign Application Priority Data
May 12, 2023 (JP) 2023-079441

(51) Int. Cl. H01L 21/768; C23C 16/02; C23C 16/26; C23C 16/511; C23C 16/52; H01J 37/32; H01L 21/02

(52) U.S. Cl. CPC H01L 21/76834; C23C 16/0281; C23C 16/26; C23C 16/511; C23C 16/52; H01J 37/32449; H01J 37/32192; H01J 2237/332

(57) ABSTRACT

A substrate processing method includes: preparing a substrate having a pattern, which includes a metal-containing layer formed on a base layer and a dielectric layer formed on the metal-containing layer; supplying a modifying gas into a processing container and selectively modifying the metal-containing layer at a sidewall of a hole or groove in the pattern; and supplying a processing gas including a carbon-containing gas into the processing container to generate plasma, and forming a graphene film selectively on the metal-containing layer at the sidewall by using the generated plasma.

### CROSS-REFERENCE TO RELATED APPLICATION

The application is a Bypass Continuation Application of PCT International Application No. PCT/JP2024/016621, filed on Apr. 30, 2024 and designating the United States, the international application being based upon and claiming the benefit of priority from Japanese Patent Application No. 2023-079441, filed on May 12, 2023, the entire contents of which are incorporated herein by reference.

### TECHNICAL FIELD

The present disclosure relates to a substrate processing method and a substrate processing apparatus.

### BACKGROUND

Patent Document 1 discloses a method including a step of providing a planarized substrate including a first material, which has a concave feature filled with a second material, a step of selectively adhering a graphene layer to the second material rather than to the first material, a step of selectively adhering a SiO₂ film to the first material rather than to the graphene layer, and a step of removing the graphene layer from the substrate. Further, Patent Document 1 discloses that the step of selectively adhering the SiO₂ film includes forming a second concave feature that is aligned with the concave feature filled with the second material. Further, Patent Document 1 discloses that the first material includes a dielectric material and the second material includes a metal layer.

### PRIOR ART DOCUMENT

### Patent Document

Patent Document 1: Japanese Patent Laid-open Publication No. 2018-182328

### SUMMARY

A substrate processing method according to the present disclosure includes: preparing a substrate having a pattern, which includes a metal-containing layer formed on a base layer and a dielectric layer formed on the metal-containing layer; supplying a modifying gas into a processing container and selectively modifying the metal-containing layer at a sidewall of a hole or groove in the pattern; and supplying a processing gas including a carbon-containing gas into the processing container to generate plasma, and forming a graphene film selectively on the metal-containing layer at the sidewall using the generated plasma.

### BRIEF DESCRIPTION OF DRAWINGS

The accompanying drawings, which are incorporated in and constitute a part of the specification, illustrate embodiments of the present disclosure, and together with the general description given above and the detailed description of the embodiments given below, serve to explain the principles of the present disclosure.

FIG. 1 is a diagram illustrating an example of a substrate processing apparatus according to an embodiment of the present disclosure.

FIG. 2 is a diagram schematically illustrating an example of a ceiling wall of a processing container according to an embodiment.

FIG. 3 is a diagram illustrating an example of a state of a substrate after forming a graphene film according to an embodiment.

FIG. 4 is a flowchart illustrating an example of film formation processing according to an embodiment.

FIG. 5 is a diagram illustrating an example of a traced cross-section of a substrate before an experiment according to an embodiment.

FIG. 6 is a diagram illustrating an example of a traced cross-section of the substrate after the experiment according to an embodiment.

### DETAILED DESCRIPTION

Reference will now be made in detail to various embodiments, examples of which are illustrated in the accompanying drawings. In the following detailed description, numerous specific details are set forth in order to provide a thorough understanding of the present disclosure. However, it will be apparent to one of ordinary skill in the art that the present disclosure may be practiced without these specific details. In other instances, well-known methods, procedures, systems, and components have not been described in detail so as not to unnecessarily obscure aspects of the various embodiments.

Hereinafter, embodiments of a substrate processing method and a substrate processing apparatus disclosed herein will be described in detail with reference to the drawings. In addition, the disclosed technique is not limited by the following embodiments.

In a wiring process for semiconductors, a copper (Cu) dual damascene method is currently used, but as semiconductors are miniaturized, RC delay has become a problem. With respect to this, wiring materials having superior characteristics with a narrow metal pitch and wiring formation methods are being studied. For example, a semi-damascene method in which a wiring metal is directly patterned (subtractive metallization) and therefore chemical mechanical polishing (CMP) is not required has been proposed. Further, a semi-damascene method using ruthenium (Ru) as a wiring material has been proposed to reduce RC delay. Furthermore, forming a graphene film on a sidewall of a wiring metal in a substrate after directly patterning the wiring metal, that is, after a subtractive etch, can be considered to reduce a resistance through a capping effect and provide protection against damage when embedding an insulator. However, when the graphene film is formed in the substrate after the subtractive etching, since the graphene film is formed at both a sidewall of a hole or groove from which the wiring metal is exposed and a bottom of the hole or groove from which an insulating film is exposed, wirings may be short-circuited via the graphene film. In addition, when a selectivity of the graphene film with respect to the sidewall of the hole or groove is prioritized, the graphene film may not be formed at a lower portion of the sidewall. Therefore, a graphene film is expected to be formed selectively on a metal-containing layer (wiring metal) exposed from a sidewall of a hole or groove.

### [Configuration of Substrate Processing Apparatus 100]

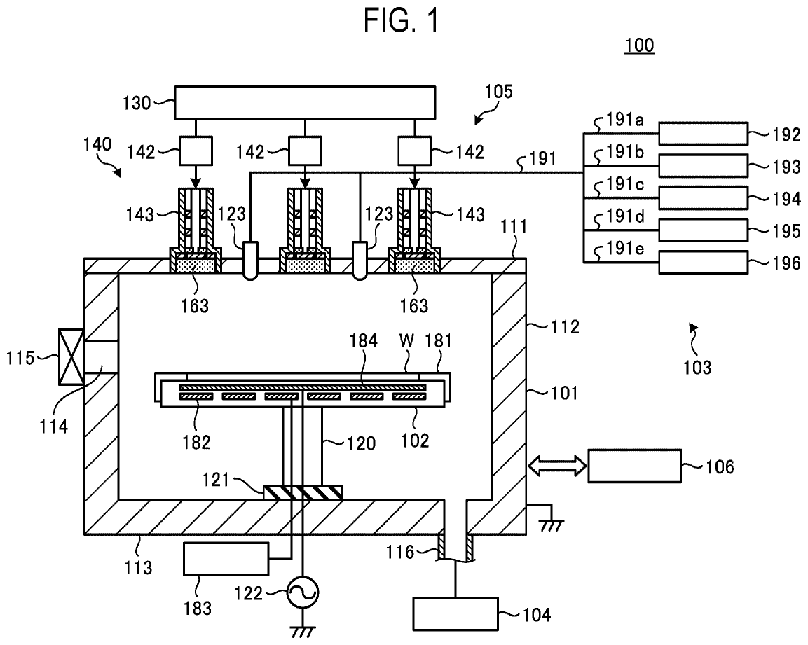

FIG. 1 is a diagram illustrating an example of a substrate processing apparatus according to one embodiment of the present disclosure. A substrate processing apparatus 100 illustrated in FIG. 1 includes a processing container 101, a stage 102, a gas supplier 103, an exhauster 104, a microwave introduction device 105, and a controller 106. The processing container 101 accommodates a substrate W in the processing container 101. The stage 102 places the substrate W on the stage 102. The gas supplier 103 supplies gases into the processing container 101. The exhauster 104 exhausts an interior of the processing container 101. The microwave introduction device 105 generates microwaves for plasma generation inside the processing container 101 and introduces the microwaves into the processing container 101. The controller 106 controls operations of individual components of the substrate processing apparatus 100.

The processing container 101 is made of, for example, a metallic material such as aluminum and an alloy of aluminum, and is formed in a substantially cylindrical shape. The processing container 101 has a plate-shaped ceiling wall 111, a bottom wall 113, and a sidewall 112 connecting the ceiling wall 111 and the bottom wall 113. The microwave introduction device 105 is provided above the processing container 101, and functions as a plasma generation means that introduces electromagnetic waves (microwaves) into the processing container 101 to generate plasma. The microwave introduction device 105 will be described in detail later.

The ceiling wall 111 has a plurality of openings into which microwave radiators of the microwave introduction device 105 and gas introduction nozzles, which will be described later, are inserted. The sidewall 112 has a load/unload port 114 for loading and unloading the substrate W, which is an object to be processed, into and from a transport chamber (not illustrated) adjacent to the processing container 101. The load/unload port 114 is opened and closed by a gate valve 115. The bottom wall 113 is provided with the exhauster 104. The exhauster 104 is provided in an exhaust pipe 116 connected to the bottom wall 113, and includes a vacuum pump and a pressure control valve. The interior of the processing container 101 is exhausted via the exhaust pipe 116 by the vacuum pump of the exhauster 104. An internal pressure of the processing container 101 is controlled by the pressure control valve.

The stage 102 is formed in a disk shape and is made of ceramic such as AlN. The stage 102 is supported by a cylindrical support 120, which is made of ceramic such as AlN and extends upward from a center of the bottom of the processing container 101. A guide ring 181 for guiding the substrate W is provided on an outer edge of the stage 102. Further, lifting pins (not illustrated) for raising or lowering the substrate W are provided in the stage 102 so as to be capable of protruding and retracting with respect to an upper surface of the stage 102.

A resistive heater 182 is embedded in the stage 102. Upon receiving power from a heater power supply, the heater 182 heats the substrate W on the stage 102 via the stage 102. Further, a thermocouple (not illustrated) is inserted into the stage 102, and based on a signal from the thermocouple, a heating temperature of the substrate W can be controlled to a predetermined temperature in a range of, for example, 200 degrees C. to 1,000 degrees C. Furthermore, an electrode 184 having approximately the same size as the substrate W is embedded in the stage 102 and above the heater 182, and a radio frequency bias power supply 122 is electrically connected to the electrode 184. Radio frequency bias power for attracting ions is applied to the stage 102 from the radio frequency bias power supply 122. In addition, the radio frequency bias power supply 122 may not be provided according to characteristics of plasma processing.

The gas supplier 103 is for introducing a plasma generation gas and a raw material gas for forming a graphene film (carbon-containing film) into the processing container 101, and includes a plurality of gas introduction nozzles 123. The gas introduction nozzles 123 are inserted into the openings formed in the ceiling wall 111 of the processing container 101. A gas supply pipe 191 is connected to the gas introduction nozzles 123. The gas supply pipe 191 branches into five branch pipes 191a, 191b, 191c, 191d, and 191e. A plasma generation gas source 192, a cleaning gas source 193, a purge gas source 194, a modifying/additive gas source 195, and a carbon-containing gas source 196 are connected to the branch pipes 191a, 191b, 191c, 191d, and 191e, respectively. The plasma generation gas source 192 supplies a rare gas (noble gas) serving as a plasma generation gas, for example, Ar gas. In addition, the gas supplier 103 may also supply, as the rare gas (noble gas) serving as the plasma generation gas, for example, He gas. The cleaning gas source 193 supplies an oxidizing gas serving as a cleaning gas, for example, O₂ gas. The purge gas source 194 supplies N₂ gas used, for example, as a purge gas. The modifying/additive gas source 195 supplies a reducing gas, for example, H₂ gas. In addition, the modifying/additive gas source 195 may supply, for example, NH₃ gas. The carbon-containing gas source 196 supplies a carbon-containing gas serving as a film formation raw material gas, for example, acetylene (C₂H₂) gas. In addition, the carbon-containing gas source 196 may supply a carbon-containing gas including a hydrocarbon gas represented by CₓH_{y} (where x and y are natural numbers) such as ethylene (C₂H₄).

In addition, although not illustrated, the branch pipes 191a, 191b, 191c, 191d, and 191e are provided with mass flow controllers for flow rate control and valves before and after the mass flow controllers. In addition, a shower plate may be provided to supply the carbon-containing gas and the modifying/additive gas to a position close to the substrate W, thereby regulating dissociation of gases. Further, the same effect may be achieved by extending nozzles for supplying the gases downward.

As described above, the microwave introduction device 105 is provided above the processing container 101, and functions as a plasma generation means that introduces electromagnetic waves (microwaves) into the processing container 101 to generate plasma.

The microwave introduction device 105 includes the ceiling wall 111 of the processing container 101, a microwave output 130, and an antenna unit 140. The ceiling wall 111 functions as a ceiling plate. The microwave output 130 generates microwaves, and distributes and outputs the microwaves to a plurality of paths. The antenna unit 140 introduces the microwaves output from the microwave output 130 into the processing container 101.

The microwave output 130 includes a microwave power supply, a microwave oscillator, an amplifier, and a distributor. The microwave oscillator is in a solid state and oscillates microwaves, for example, at 860 MHz (for example, a PLL oscillation). In addition, a frequency of the microwaves is not limited to 860 MHZ, and may be in a range of 700 MHz to 10 GHz, such as 2.45 GHz, 8.35 GHz, 5.8 GHz, or 1.98 GHz. The amplifier amplifies the microwaves oscillated by the microwave oscillator. The distributor distributes the microwaves amplified by the amplifier to the plurality of paths. The distributor distributes the microwaves while matching impedances of an input side and an output side.

The antenna unit 140 includes a plurality of antenna modules. Each of the plurality of antenna modules introduces the microwaves distributed by the distributor of the microwave output 130 into the processing container 101. All of the plurality of antenna modules have a same configuration. Each antenna module includes an amplifier 142 that mainly amplifies and outputs the distributed microwaves and a microwave radiator 143 that radiates the microwaves output from the amplifier 142 into the processing container 101.

The amplifier 142 includes a phase shifter, a variable gain amplifier, a main amplifier, and an isolator. The phase shifter changes phases of the microwaves. The variable gain amplifier regulates power levels of the microwaves input to the main amplifier. The main amplifier is configured as a solid state amplifier. The isolator separates the reflected microwaves that are reflected from an antenna portion of the microwave radiator 143, which will be described later, and directed toward the main amplifier.

A plurality of microwave radiators 143 are provided in the ceiling wall 111, as illustrated in FIG. 1. Further, each microwave radiator 143 includes a cylindrical outer conductor, and an inner conductor provided coaxially with the outer conductor inside the outer conductor. The microwave radiator 143 includes a coaxial tube having a microwave transmission path between the outer conductor and the inner conductor, and the antenna portion that radiates microwaves into the processing container 101. A microwave transmission plate 163 inserted into the ceiling wall 111 is provided to face a lower surface of the antenna portion, and a lower surface of the microwave transmission plate 163 is exposed to the internal space of the processing container 101. The microwaves transmitted through the microwave transmission plate 163 generate plasma in the internal space of the processing container 101. That is, the microwave radiator 143 is an example of a plasma source.

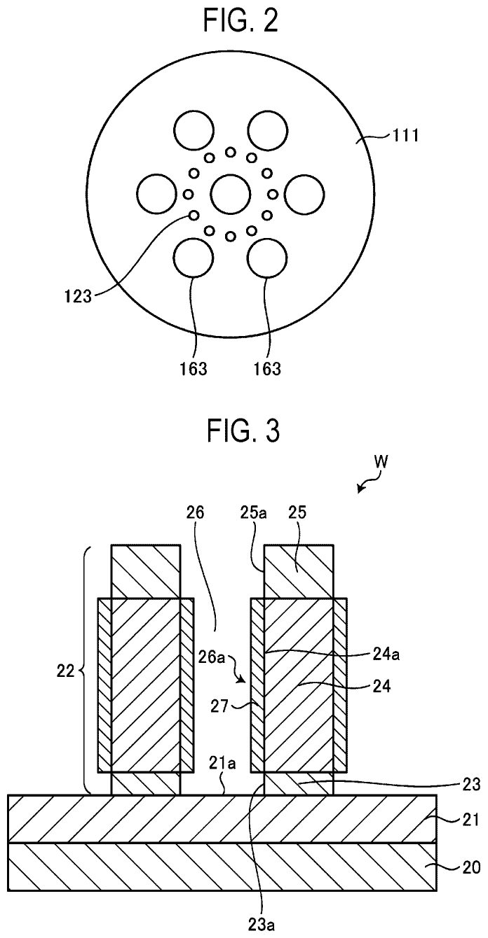

FIG. 2 is a diagram schematically illustrating an example of the ceiling wall of the processing container according to the present embodiment. As illustrated in FIG. 2, in the present embodiment, seven microwave radiators 143 are provided, and the microwave transmission plates 163 corresponding to the microwave radiators 143 are disposed evenly in a hexagonal close-packed arrangement. That is, among the seven microwave transmission plates 163, one microwave transmission plate 163 is disposed at a center of the ceiling wall 111, and the other six microwave transmission plates 163 are disposed around the one microwave transmission plate 163. These seven microwave transmission plates 163 are disposed such that adjacent microwave transmission plates 163 are equi-spaced from one another. In addition, the center of the ceiling wall 111 is an example of a center region, and a region around the microwave radiator 143 disposed at the center of the ceiling wall 111 is an example of an edge region. That is, one microwave radiator 143 is disposed in the center region, and six microwave radiators 143 are disposed in the edge region. Further, the plurality of gas introduction nozzles 123 of the gas supplier 103 are disposed to surround a periphery of the central microwave transmission plate 163. In addition, the number of microwave radiators 143 is not limited to seven.

Returning to the explanation of FIG. 1, the controller 106 is typically configured as a computer and controls individual components of the substrate processing apparatus 100. The controller 106 includes a storage that stores process recipes, which are process sequences and control parameters for the substrate processing apparatus 100, an input means, a display, and the like, and can perform predetermined control according to a selected process recipe.

For example, the controller 106 controls individual components of the substrate processing apparatus 100 to perform a substrate processing method to be described later. As a detailed example, the controller 106 executes a process of preparing a substrate W having a pattern, which includes a metal-containing layer formed on a base layer and a dielectric layer formed on the metal-containing layer, and loading the substrate W into the processing container 101. The controller 106 executes a process of supplying a modifying gas into the processing container 101 to selectively modify the metal-containing layer at a sidewall of a hole or groove in the pattern. Here, as the modifying gas, H₂ gas supplied from the modifying/additive gas source 195 may be used. Further, the modifying gas may also include Ar gas supplied from the plasma generation gas source 192. The controller 106 executes a process of supplying a processing gas including a carbon-containing gas into the processing container 101 to generate plasma, and forming a graphene film selectively on the metal-containing layer at the sidewall by using the generated plasma. Here, as the carbon-containing gas, acetylene (C₂H₂) gas supplied from the carbon-containing gas source 196 may be used. Further, the carbon-containing gas may also include Ar gas supplied from the plasma generation gas source 192 or H₂ gas supplied from the modifying/additive gas source 195.

[Substrate after Forming Graphene Film at Sidewall of Pattern]

Next, the substrate W after forming a graphene film selectively at a sidewall of a hole or groove in a pattern will be described with reference to FIG. 3. FIG. 3 is a diagram illustrating an example of a state of a substrate after forming a graphene film according to the present embodiment. The substrate W illustrated in FIG. 3 is in a state in which the graphene film is formed at a sidewall of a wiring metal in the substrate W after a subtractive etch. The substrate W includes a base layer 21 formed on a silicon substrate 20. Further, a pattern 22 is formed on the base layer 21. The pattern 22 includes, in an order from a side of the base layer 21, a barrier layer 23, a metal-containing layer 24, and a dielectric layer 25. Further, the pattern 22 has, for example, a groove 26 formed therein. Alternatively, the groove 26 may be a hole. In the example of FIG. 3, in the groove 26, a bottom of the groove 26 is referred to as a bottom 21a, and a sidewall of the groove 26 is referred to as a sidewall 26a. Further, in the sidewall 26a, a sidewall of the barrier layer 23 is referred to as a sidewall 23a, a sidewall of the metal-containing layer 24 is referred to as a sidewall 24a, and a sidewall of the dielectric layer 25 is referred to as a sidewall 25a. An aspect ratio of the groove 26 may be, for example, 3 or more. With this configuration, a graphene film 27 can be suppressed from being formed on the bottom 21a of the groove 26.

In addition, the silicon substrate 20 may be made of, for example, silicon or silicon oxide. The base layer 21 may be, for example, a film formed using tetra ethyl ortho silicate (TEOS: Si(OC₂H₅)₄), a silicon oxide film such as SiO₂, an aluminum oxide film such as AlOₓ, or a low-k film such as SiOC. In FIG. 3, the base layer 21 is disposed on the silicon substrate 20 for illustrative purposes, but the base layer 21 may also be an interlayer insulating layer disposed between the silicon substrate 20 and a lower layer stacked on the silicon substrate 20. Further, each layer may be referred to as a film. The barrier layer 23 may be, for example, a nitride film such as titanium nitride (TiN) or tantalum nitride (TaN). The metal-containing layer 24 may be, for example, a metal film such as copper (Cu), tungsten (W), ruthenium (Ru), nickel (Ni), cobalt (Co), or molybdenum (Mo), or may be a metal-containing film containing these metals. The dielectric layer 25 may be, for example, a nitride film such as silicon nitride (Si₃N₄) or aluminum nitride (AlN).

In the sidewall 26a of the groove 26, the graphene film 27 is formed at the sidewall 24a of the metal-containing layer 24. In addition, the graphene film 27 is, for example, a multi-layer graphene (MLG). On the other hand, in the sidewall 26a of the groove 26, the graphene film 27 is not formed at the sidewall 23a of the barrier layer 23 and the sidewall 25a of the dielectric layer 25. Further, the graphene film 27 is not formed at the bottom 21a of the groove 26. That is, the graphene film 27 is formed selectively at the sidewall 24a of the metal-containing layer 24. In addition, even in a case in which the graphene film 27 is formed at the sidewall 23a of the barrier layer 23, insulation between the metal-containing layers 24 on both sides of the groove 26 is maintained as long as the graphene film 27 is not formed at the bottom 21a. Further, an interior of the groove 26 may, for example, be filled with a dielectric (insulator), or may be an empty space.

### [Selectivity of Graphene Film Formation]

Here, selectivity of graphene film formation in an experiment of forming a graphene film by using blanket substrates, in which films corresponding to the base layer 21, the barrier layer 23, the metal-containing layer 24, and the dielectric layer 25 are formed on a silicon substrate, respectively, will be described. A silicon oxide film (SiO₂ film) as the film corresponding to the base layer 21 and a titanium nitride film as the film corresponding to the barrier layer 23 are formed in blanket substrates, respectively. A ruthenium film as the film corresponding to the metal-containing layer 24 and an annealed ruthenium film as the film corresponding to the metal-containing layer 24 are formed in blanket substrates, respectively. A silicon nitride film as the film corresponding to the dielectric layer 25 is formed in a blanket substrate.

With respect to each blanket substrate, a processing of forming a graphene film was performed under the same processing condition. In the processing, the substrate processing apparatus 100 was used. Further, the processing condition was the following processing condition A.

### <Processing Condition A>

Pressure of the processing container 101: 10 mTorr to 100 mTorr (1.33 Pa to 13.3 Pa)
Processing gas: C₂H₂ gas: 0.5 sccm to 5.0 sccm
   H₂ gas: 0.1 sccm to 1.0 sccm
   Ar gas: 50 sccm to 500 sccm
Radio frequency (plasma) power:
   Center region/edge region: 100 W/100 W×6 to 250 W/250 W×6
Substrate temperature: 300 degrees C. to 500 degrees C.

As a result of the graphene film formation, no graphene film was formed in the blanket substrates in which the silicon oxide film (SiO₂) and the silicon nitride film were formed, respectively. On the other hand, a graphene film was formed on the blanket substrates in which the ruthenium film, the annealed ruthenium film, and the titanium nitride film were formed, respectively. From these results, it can be recognized that the blanket substrates of the ruthenium film and the annealed ruthenium film exhibit selectivity with respect to the blanket substrates of the silicon oxide film (SiO₂) and the silicon nitride film. Further, it can be recognized that the blanket substrates of the ruthenium film and the annealed ruthenium film do not exhibit selectivity with respect to the blanket substrate in which the titanium nitride film was formed.

Subsequently, with respect to the blanket substrates of the ruthenium film and the annealed ruthenium film, in which the graphene film was formed, surface resistivity ρs [ohms/sq] was measured before and after the graphene film formation. In the blanket substrate of the ruthenium film, the surface resistivity ρs decreased from 7.2 [ohms/sq] before the graphene film formation to 4.1 [ohms/sq] after the graphene film formation. That is, a rate of change in surface resistance ARs in the blanket substrate of the ruthenium film was −44%. In the blanket substrate of the annealed ruthenium film, the surface resistivity ρs decreased from 4.1 [ohms/sq] before the graphene film formation to 4.0 [ohms/sq] after the graphene film formation. That is, a rate of change in surface resistance ARs in the blanket substrate of the annealed ruthenium film was-2.4%. From these results, it can be recognized that, in the blanket substrates of the ruthenium film and the annealed ruthenium film, the resistance is reduced by a capping effect of the graphene film.

### [Substrate Processing Method]

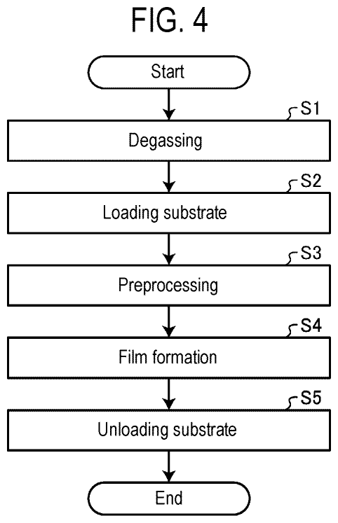

Next, as a substrate processing method, film formation processing according to the present embodiment will be described. FIG. 4 is a flowchart illustrating an example of the film formation processing according to the present embodiment.

The controller 106 of the substrate processing apparatus 100 executes a degassing process of removing residual oxygen in a state in which the interior of the processing container 101 has been cleaned (step S1). The controller 106 controls the gate valve 115 to open the load/unload port 114. When the load/unload port 114 is open, a dummy wafer is loaded into a processing space in the processing container 101 via the load/unload port 114, and is placed on the stage 102. The controller 106 then controls the gate valve 115 to close the load/unload port 114.

The controller 106 controls the gas supplier 103 to supply a hydrogen-containing gas from the plurality of gas introduction nozzles 123 into the processing container 101. Further, the controller 106 controls the exhauster 104 to control the internal pressure of the processing container 101 to a predetermined pressure (for example, 50 mTorr to 1 Torr (6.67 Pa to 133 Pa)). As the hydrogen-containing gas or a nitrogen-containing gas in the degassing process, for example, H₂ gas or N₂ gas, a mixed gas of H₂ gas and N₂ gas, or a mixed gas of H₂ gas and/or N₂ gas with Ar gas may be used. The controller 106 controls the microwave introduction device 105 to ignite plasma. The controller 106 executes the degassing process for a predetermined time (for example, 120 to 600 seconds) by using plasma of the hydrogen-containing gas or the nitrogen-containing gas. In the degassing process, oxidizing components such as O₂ and H₂O remaining in the processing container 101 are discharged as O-containing radicals. In addition, the dummy wafer may not be used in the degassing process. Further, the degassing process may be omitted.

When the degassing process is completed, the controller 106 controls the gate valve 115 to open the load/unload port 114. When the load/unload port 114 is opened, the substrate W having the pattern 22 is loaded into the processing space of the processing container 101 via the load/unload port 114, and is placed on the stage 102. That is, the controller 106 controls the substrate processing apparatus 100 to load the substrate W having the pattern 22, which includes the metal-containing layer 24 formed on the base layer 21 and the dielectric layer 25 formed on the metal-containing layer 24, into the processing container 101 (step S2). The controller 106 may also be a control device for an overall substrate processing system (not illustrated), which includes the substrate processing apparatus 100 and a transport device of the transport chamber (not illustrated) adjacent to the processing container 101. The controller 106 then controls the gate valve 115 to close the load/unload port 114. Step S2 is an example of a process of preparing the substrate W having the pattern 22, which includes the metal-containing layer 24 formed on the base layer 21 and the dielectric layer 25 formed on the metal-containing layer 24.

The controller 106 controls the exhauster 104 to reduce the internal pressure of the processing container 101 to a predetermined pressure (for example, 50 mTorr to 1 Torr). The controller 106 controls a heater power supply 183 to heat the substrate W to a predetermined temperature (for example, 250 degrees C. to 550 degrees C.). The controller 106 controls the gas supplier 103 to supply a hydrogen-containing gas serving as a modifying gas from the gas introduction nozzles 123 into the processing container 101. The hydrogen-containing gas is a gas that includes hydrogen (H₂) gas and an inert gas (Ar gas). Further, the hydrogen-containing gas may include NH₃ gas. Here, a flow rate ratio of the inert gas to the hydrogen-containing gas may be in a range of 200:2 to 50:50. The controller 106 executes a preprocessing process for a predetermined time (for example, 5 seconds to 15 minutes) in which the hydrogen-containing gas is used to selectively modify the metal-containing layer 24 at the sidewall 26a of the groove 26 in the pattern 22 (step S3). That is, the controller 106 executes an annealing process as the preprocessing process. In the preprocessing process, a surface of the sidewall 24a of the metal-containing layer 24 is modified. Here, modification refers to at least one of reduction or activation. For example, in the preprocessing process, an oxide film unintentionally formed on the surface of the sidewall 24a of the metal-containing layer 24 when transporting the substrate W and the like is reduced and removed.

In addition, in the preprocessing process, a plasma process may be performed in addition to or instead of the annealing processing. In a case in which the plasma processing is performed, the internal pressure of the processing container 101 is reduced to a predetermined pressure (for example, 50 mTorr to 1 Torr), and, for example, a hydrogen-containing gas is supplied into the processing container 101. Further, during the plasma processing, the microwave introduction device 105 is controlled such that predetermined microwave power (for example, 100 W to 1,500 W) is supplied into the processing container 101 to ignite plasma. In addition, a processing time of the plasma processing is, for example, from 5 seconds to 15 minutes.

When the preprocessing process is completed, the controller 106 controls the exhauster 104 to reduce the internal pressure of the processing container 101 to a predetermined pressure (for example, 1 mTorr to 100 mTorr (0.133 Pa to 13.3 Pa)). Specifically, the predetermined pressure may be in a range of 50 mTorr to 100 mTorr (6.67 Pa to 13.3 Pa). The controller 106 controls the heater power supply 183 to heat the substrate W to a predetermined temperature (for example, 250 degrees C. to 550 degrees C.). In addition, after the plasma ignition, the temperature of the substrate W is controlled by considering heat input from the plasma to the substrate W. The controller 106 controls the gas supplier 103 to supply a carbon-containing gas as a processing gas from the gas introduction nozzles 123 into the processing container 101. The carbon-containing gas is a gas that includes a hydrocarbon gas represented by CₓH_{y} (where x and y are natural numbers) (for example, at least one of C₂H₂ gas or C₂H₄ gas) and an inert gas (for example, Ar gas). Further, the processing gas may include a hydrogen-containing gas. The controller 106 controls the microwave introduction device 105 to ignite plasma with predetermined power (for example, 300 W to 3,000 W). The predetermined power may be, for example, 1,500 W or less. The controller 106 executes a film formation process for a predetermined time (for example, 5 seconds to 15 minutes) in which a graphene film is formed selectively on the metal-containing layer 24 (sidewall 24a) at the sidewall 26a by using plasma of the carbon-containing gas (step S4).

When the film formation process is completed, the controller 106 stops supplying microwaves to stop plasma generation. Further, the controller 106 controls the gate valve 115 to open the load/unload port 114. The controller 106 controls the substrate processing apparatus 100 such that the lifting pins (not illustrated) protrude from the upper surface of the stage 102 to lift up the substrate W. When the load/unload port 114 is opened, the substrate W is unloaded from the interior of the processing container 101 via the load/unload port 114 by an arm of the transport chamber (not illustrated). That is, the controller 106 controls the substrate processing apparatus 100 to unload the substrate W from the processing container 101 (step S5). As described above, since the metal-containing layer 24 is modified before the graphene film formation, the graphene film 27 may be formed selectively on the exposed metal-containing layer 24 (sidewall 24a) at the sidewall 26a of the groove 26. Further, since the graphene film 27 may be formed selectively on the metal-containing layer 24, it is possible to reduce damage to the metal-containing layer 24 when forming the interlayer insulating film, and to reduce a wiring resistance by the capping effect. Further, by forming the graphene film at the sidewall (sidewall 24a) of the metal wiring (metal-containing layer 24), a capacitance between metal wirings may be reduced. Further, the present embodiment may also be applied to air gap formation.

### [Experimental Results]

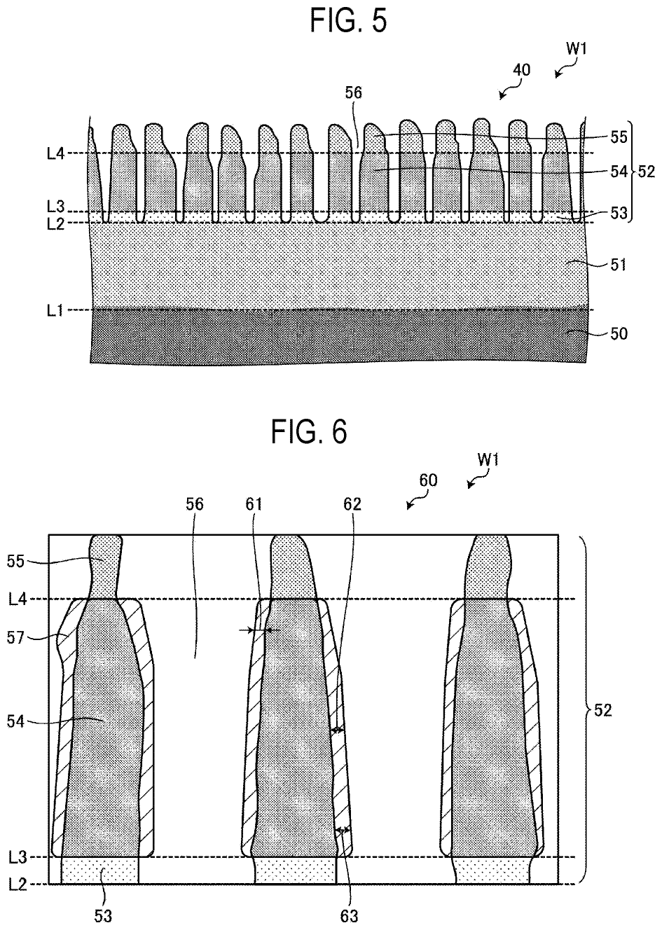

Next, experimental results in the present embodiment will be described with reference to FIGS. 5 and 6. FIG. 5 is a diagram illustrating an example of a traced cross-section of a substrate before an experiment according to the present embodiment. A cross-section 40 of a substrate W1 illustrated in FIG. 5 represents a state before graphene film formation, and a base layer 51 is formed on a silicon substrate 50. Further, a pattern 52 is formed on the base layer 51. The pattern 52 includes, sequentially from a side of the base layer 51, a barrier layer 53, a metal-containing layer 54, and a dielectric layer 55. Further, a plurality of grooves 56 are formed in the pattern 52. The substrate W1 is an example of the substrate W. In the example of the substrate W1, the barrier layer 53 has a film thickness of about 2 to 3 nm, the metal-containing layer 54 has a film thickness of about 40 to 50 nm, and the dielectric layer 55 has a film thickness of about 20 nm. In FIG. 5, dashed line L1 indicates a lower surface of the base layer 51, and dashed line L2 indicates an interface between the base layer 51 and the barrier layer 53. Dashed line L3 indicates an interface between the barrier layer 53 and the metal-containing layer 54. Dashed line L4 indicates an interface between the metal-containing layer 54 and the dielectric layer 55. In this experiment, in order to form a graphene film at a sidewall of the metal-containing layer 54 exposed in the groove 56, film formation processing was performed on the substrate W1 under each of the following processing conditions 1 and 2.

### <Processing Condition 1>

Preprocessing process (annealing processing)
Pressure of the processing container 101:400 mTorr (53.3 Pa)
Processing gas: Ar/H₂ mixed gas: 100/2 sccm
Processing temperature: 380 degrees C.
Processing time: 600 seconds
Film formation process
Pressure of the processing container 101:50 mTorr (6.67 Pa)
Radio frequency power: center region/edge region: 200 W/180 W×6
Processing gas: Ar/C₂H₂ mixed gas: 100/1 sccm
Processing temperature: 380 degrees C.
Processing time: 300 seconds
Radio frequency bias: 0 W

### <Processing Condition 2>

Preprocessing process (annealing processing)
Pressure of the processing container 101:400 mTorr (53.3 Pa)
Processing gas: Ar/H₂ mixed gas: 100/2 sccm
Processing temperature: 380 degrees C.
Processing time: 600 seconds
Film formation process
Pressure of the processing container 101:100 mTorr (13.3 Pa)
Radio frequency power: center region/edge region: 200 W/180 W×6
Processing gas: Ar/C₂H₂ mixed gas: 300/3 sccm
Processing temperature: 380 degrees C.
Processing time: 200 seconds
Radio frequency bias: 0 W

FIG. 6 is a diagram illustrating an example of a traced cross-section of the substrate after the experiment according to the present embodiment. A cross-section 60 illustrated in FIG. 6 is an enlarged view of a portion of the pattern 52 of the substrate W1 after film formation processing under processing condition 1. As illustrated in the cross-section 60, in the substrate W1, a graphene film 57 was formed at the sidewall of the metal-containing layer 54 among sidewalls of each groove 56. On the other hand, in the substrate W1, no graphene film 57 was formed at sidewalls of the barrier layer 53 and the dielectric layer 55 among the sidewalls of the groove 56. Further, no graphene film 57 was formed at a bottom of the groove 56 indicated by dashed line L2. That is, it can be recognized that in the substrate W1, the graphene film 57 was formed selectively at the sidewall of the metal-containing layer 54 among the sidewalls of the groove 56. Further, the film thickness of the graphene film 57 was approximately 1.2 nm at a top 61 of the groove 56, and approximately 1.6 nm at a middle 62 and a bottom 63, which indicates that the film was formed with a substantially uniform thickness. Further, by setting the microwave power of the microwave radiator 143 in the center region and the microwave power of each microwave radiator 143 in the edge region to be different from each other, in-plane uniformity of the graphene film 57 in the substrate W1 was improved compared to a case in which the powers are the same as each other. In addition, although not illustrated, under processing condition 2 as well, the graphene film 57 was formed selectively at the sidewall of the metal-containing layer 54 in the same manner as under processing condition 1. Further, in a case in which the preprocessing process was not performed and the sidewall of the metal-containing layer 54 was not modified under both processing conditions 1 and 2, the graphene film could not be formed selectively at the sidewall of the metal-containing layer 54. That is, it is considered that, in the case in which the preprocessing process was not performed and the sidewall of the metal-containing layer 54 was not modified, the selectivity deteriorated due to an increased incubation time or the graphene film 57 was not formed at all.

According to the present embodiment described above, the substrate processing apparatus 100 includes the processing container 101 and the controller 106. The controller 106 executes the process of loading the substrate W, which has the pattern 22 including the metal-containing layer 24 formed on the base layer 21 and the dielectric layer 25 formed on the metal-containing layer 24, into the processing container 101, the process of supplying a modifying gas into the processing container 101 and selectively modifying the metal-containing layer 24 at the sidewall 26a of the hole or groove 26 in the pattern 22, and the process of supplying a processing gas including the carbon-containing gas into the processing container 101 to generate plasma and forming the graphene film 27 selectively on the metal-containing layer 24 at the sidewall 26a by using the generated plasma. As a result, the graphene film 27 can be formed selectively on the metal-containing layer 24 exposed from the sidewall 26a of the hole or groove 26.

Further, according to the present embodiment, the modifying gas includes an inert gas and a hydrogen-containing gas. As a result, the surface of the sidewall 24a of the metal-containing layer 24 can be modified (reduced/activated).

Further, according to the present embodiment, the flow rate ratio of the inert gas to the hydrogen-containing gas is in the range of 200:2 to 50:50. As a result, the surface of the sidewall 24a of the metal-containing layer 24 can be modified (reduced/activated).

Further, according to the present embodiment, the inert gas includes at least one of He gas, Ar gas, or N₂ gas. As a result, substances removed from the sidewall 24a can be discharged from the processing container 101.

Further, according to the present embodiment, the hydrogen-containing gas includes at least one of H₂ gas or NH₃ gas. As a result, the surface of the sidewall 24a of the metal-containing layer 24 can be modified.

Further, according to the present embodiment, plasma is generated by microwaves. As a result, the graphene film 27 can be formed selectively on the metal-containing layer 24 exposed from the sidewall 26a of the hole or groove 26. Further, since the plasma generated by microwaves has a low electron temperature, damage to the substrate W can be suppressed. Further, since a plasma density is high, an amount of active species generated by excitation can be increased. With this configuration, the amount of active species reaching the bottom of the hole or groove increases relatively, which is effective for film formation at the bottom and the sidewall of the hole or groove.

Further, according to the present embodiment, power for plasma generation is in a range of 500 W to 3,000 W. As a result, the graphene film 27 can be formed selectively on the metal-containing layer 24 exposed from the sidewall 26a of the hole or groove 26.

Further, according to the present embodiment, the process of forming the graphene film includes generating plasma at an internal pressure of the processing container 101 within the range of 10 m Torr to 100 mTorr. As a result, the graphene film 27 can be formed selectively on the metal-containing layer 24 exposed from the sidewall 26a of the hole or groove 26.

Further, according to the present embodiment, the metal-containing layer 24 contains at least one of Ru, Co, or Cu. As a result, the graphene film 27 can be formed selectively on the metal-containing layer 24 exposed from the sidewall 26a of the hole or groove 26.

Further, according to the present embodiment, the dielectric layer 25 is either a silicon nitride layer or an aluminum nitride layer. As a result, at the sidewall 26a of the hole or groove 26, the graphene film 27 can be formed on the metal-containing layer 24 without being formed on the dielectric layer 25.

Further, according to the present embodiment, the substrate W further includes the barrier layer 23 between the base layer 21 and the metal-containing layer 24. As a result, even in the case in which the barrier layer 23 is included, the graphene film 27 can be formed selectively on the metal-containing layer 24 exposed from the sidewall 26a of the hole or groove 26.

Further, according to the present embodiment, the barrier layer 23 is either a titanium nitride layer or a tantalum nitride layer. As a result, even in the case in which the barrier layer 23 is included, the graphene film 27 can be formed selectively on the metal-containing layer 24 exposed from the sidewall 26a of the hole or groove 26.

Further, according to the present embodiment, the aspect ratio of the hole or groove 26 is 3 or more. As a result, the graphene film 27 can be suppressed from being formed at the bottom 21a of the groove 26.

Further, according to the present embodiment, the processing container 101 is configured such that one or more microwave radiators 143 are disposed both in a center region of the ceiling wall 111 of the processing container 101 and in an edge region surrounding the center region. Further, power of microwaves radiated into the processing container 101 from the microwave radiator 143 disposed in the center region differs from power of microwaves radiated into the processing container 101 from the microwave radiators 143 disposed in the edge region. As a result, the in-plane uniformity of the graphene film 27 in the substrate W can be improved.

Further, according to the present embodiment, one microwave radiator 143 is disposed in the center region, and six microwave radiators 143 are disposed in the edge region at equal intervals in a circumferential direction. As a result, the in-plane uniformity of the graphene film 27 in the substrate W can be improved.

The embodiments disclosed herein should be considered to be exemplary and not limitative in all respects. The above embodiments may be omitted, replaced, or modified in various forms without departing from the scope of the appended claims and their gist.

Further, the above embodiment has described the substrate processing apparatus 100 having the plurality of microwave radiators 143, but the present disclosure is not limited thereto. For example, the above-described film formation processing may also be executed in a substrate processing apparatus having a single microwave radiator.

Further, by way of example, the above embodiment has described the substrate processing apparatus 100 that performs processing such as etching or film formation on the substrate W by using microwave plasma as a plasma source, but the technique disclosed herein is not limited thereto. The plasma source is not limited to microwave plasma as long as the apparatus performs processing on the substrate W using plasma, and for example, capacitively coupled plasma, inductively coupled plasma, magnetron plasma, or any other plasma source may be used.

The present disclosure may be configured as the following configurations.

(1) A substrate processing method including:
preparing a substrate having a pattern, which includes a metal-containing layer formed on a base layer and a dielectric layer formed on the metal-containing layer;
supplying a modifying gas into a processing container and selectively modifying the metal-containing layer at a sidewall of a hole or groove in the pattern; and
supplying a processing gas including a carbon-containing gas into the processing container to generate plasma, and forming a graphene film selectively on the metal-containing layer at the sidewall by using the generated plasma.

(2) The substrate processing method of (1), wherein the modifying gas includes an inert gas and a hydrogen-containing gas.

(3) The substrate processing method of (2), wherein a flow rate ratio of the inert gas to the hydrogen-containing gas is in a range of 200:2 to 50:50.

(4) The substrate processing method of (2) or (3), wherein the inert gas includes at least one of He gas, Ar gas, or N₂ gas.

(5) The substrate processing method of any one of (2) to (4), wherein the hydrogen-containing gas includes at least one of H₂ gas or NH₃ gas.

(6) The substrate processing method of any one of (1) to (5), wherein the plasma is generated by microwaves.

(7) The substrate processing method of any one of (1) to (6), wherein power for generating the plasma is in a range of 500 W to 3,000 W.

(8) The substrate processing method of any one of (1) to (7), wherein the forming the graphene film includes generating the plasma at an internal pressure of the processing container in a range of 10 mTorr to 100 mTorr.

(9) The substrate processing method of any one of (1) to (8), wherein the metal-containing layer includes at least one of Ru, Co, or Cu.

(10) The substrate processing method of any one of (1) to (9), wherein the dielectric layer is either a silicon nitride layer or an aluminum nitride layer.

(11) The substrate processing method of any one of (1) to (10), wherein the substrate further includes a barrier layer disposed between the base layer and the metal-containing layer.

(12) The substrate processing method of (11), wherein the barrier layer is either a titanium nitride layer or a tantalum nitride layer.

(13) The substrate processing method of any one of (1) to (12), wherein an aspect ratio of the hole or groove is 3 or more.

(14) The substrate processing method of any one of (1) to (13), wherein the processing container is configured such that one or more microwave radiators are disposed both in a center region of a ceiling wall of the processing container and an edge region surrounding the center region, and
wherein power of microwaves radiated into the processing container from the one or more microwave radiators disposed in the center region differs from power of microwaves radiated into the processing container from the one or more microwave radiators disposed in the edge region.

(15) The substrate processing method of (14), wherein a single microwave radiator is disposed in the center region, and
wherein six microwave radiators are disposed in the edge region at equal intervals in a circumferential direction.

(16) A substrate processing apparatus including:
a processing container configured to accommodate a substrate having a pattern, which includes a metal-containing layer formed on a base layer and a dielectric layer formed on the metal-containing layer;
a stage on which the substrate is placed;
a ceiling wall facing the stage;
at least one plasma source disposed on the ceiling wall;
a gas source configured to supply a processing gas into the processing container; and
a controller,
wherein the controller is configured to control the substrate processing apparatus to load the substrate into the processing container,
wherein the controller is further configured to control the substrate processing apparatus to supply a modifying gas into the processing container and selectively modify the metal-containing layer at a sidewall of a hole or groove in the pattern; and
wherein the controller is further configured to control the substrate processing apparatus to supply the processing gas including a carbon-containing gas into the processing container to generate plasma, and form a graphene film selectively on the metal-containing layer at the sidewall by using the generated plasma.

According to the present disclosure in some embodiments, it is possible to form a graphene film selectively on a metal-containing layer exposed from a sidewall of a hole or a groove.

While certain embodiments have been described, these embodiments have been presented by way of example only, and are not intended to limit the scope of the disclosures. Indeed, the embodiments described herein may be embodied in a variety of other forms. Furthermore, various omissions, substitutions and changes in the form of the embodiments described herein may be made without departing from the spirit of the disclosures. The accompanying claims and their equivalents are intended to cover such forms or modifications as would fall within the scope and spirit of the disclosures.

What is claimed is:

1. A substrate processing method comprising:
preparing a substrate having a pattern, which includes a metal-containing layer formed on a base layer and a dielectric layer formed on the metal-containing layer;
supplying a modifying gas into a processing container and selectively modifying the metal-containing layer at a sidewall of a hole or groove in the pattern; and
supplying a processing gas including a carbon-containing gas into the processing container to generate plasma, and forming a graphene film selectively on the metal-containing layer at the sidewall by using the generated plasma.

2. The substrate processing method of claim 1, wherein the modifying gas includes an inert gas and a hydrogen-containing gas.

3. The substrate processing method of claim 2, wherein a flow rate ratio of the inert gas to the hydrogen-containing gas is in a range of 200:2 to 50:50.

4. The substrate processing method of claim 3, wherein the inert gas includes at least one of He gas, Ar gas, or N₂ gas.

5. The substrate processing method of claim 3, wherein the hydrogen-containing gas includes at least one of H₂ gas or NH₃ gas.

6. The substrate processing method of claim 2, wherein the inert gas includes at least one of He gas, Ar gas, or N₂ gas.

7. The substrate processing method of claim 2, wherein the hydrogen-containing gas includes at least one of H₂ gas or NH₃ gas.

8. The substrate processing method of claim 1, wherein the plasma is generated by microwaves.

9. The substrate processing method of claim 8, wherein power for generating the plasma is in a range of 500 W to 3,000 W.

10. The substrate processing method of claim 1, wherein power for generating the plasma is in a range of 500 W to 3,000 W.

11. The substrate processing method of claim 1, wherein the forming the graphene film includes generating the plasma at an internal pressure of the processing container in a range of 10 mTorr to 100 mTorr.

12. The substrate processing method of claim 1, wherein the metal-containing layer includes at least one of Ru, Co, or Cu.

13. The substrate processing method of claim 1, wherein the dielectric layer is either a silicon nitride layer or an aluminum nitride layer.

14. The substrate processing method of claim 1, wherein the substrate further includes a barrier layer disposed between the base layer and the metal-containing layer.

15. The substrate processing method of claim 14, wherein the barrier layer is either a titanium nitride layer or a tantalum nitride layer.

16. The substrate processing method of claim 1, wherein an aspect ratio of the hole or groove is 3 or more.

17. The substrate processing method of claim 1, wherein the processing container is configured such that one or more microwave radiators are disposed both in a center region of a ceiling wall of the processing container and in an edge region surrounding the center region, and
wherein power of microwaves radiated into the processing container from the one or more microwave radiators disposed in the center region differs from power of microwaves radiated into the processing container from the one or more microwave radiators disposed in the edge region.

18. The substrate processing method of claim 17, wherein a single microwave radiator is disposed in the center region, and
wherein six microwave radiators are disposed in the edge region at equal intervals in a circumferential direction.

19. A substrate processing apparatus comprising:
a processing container configured to accommodate a substrate having a pattern, which includes a metal-containing layer formed on a base layer and a dielectric layer formed on the metal-containing layer;
a stage on which the substrate is placed;
a ceiling wall facing the stage;
at least one plasma source disposed on the ceiling wall;
a gas source configured to supply a processing gas into the processing container; and
a controller,
wherein the controller is configured to control the substrate processing apparatus to load the substrate into the processing container,
wherein the controller is further configured to control the substrate processing apparatus to supply a modifying gas into the processing container and selectively modify the metal-containing layer at a sidewall of a hole or groove in the pattern; and
wherein the controller is further configured to control the substrate processing apparatus to supply the processing gas including a carbon-containing gas into the processing container to generate plasma, and form a graphene film selectively on the metal-containing layer at the sidewall by using the generated plasma.
